(19) United States
(12) Patent Application Publication
(10) Pub. No.: US 2014/0348200 A1
(43) Pub. Date: Nov. 27, 2014

(54) MIDDLE-INFRARED VOLUMETRIC BRAGG GRATING BASED ON ALKALI HALIDE COLOR CENTER CRYSTALS

(71) Applicant: The UAB Research Foundation, Birminghan, AL (US)

(72) Inventors: Anitha Arumugam, Birmingham, AL (US); Dmitry V. Martyshkin, Birmingham, AL (US); Vladimir V. Fedorov, Birmingham, AL (US); David J. Hilton, Bessemer, AL (US); Sergey B. Mirov, Vestavia Hills, AL (US)

(21) Appl. No.: 14/371,970

(22) PCT Filed: Jan. 14, 2013
(86) PCT No.: PCT/US2013/021500

§ 371 Date: Jul. 11, 2014

Related U.S. Application Data
(60) Provisional application No. 61/586,086, filed on Jan. 12, 2012.

(51) Int. Cl. H01S 3/08; G02B 5/18; G03F 7/20; G02B 6/124

(52) U.S. Cl. CPC H01S 3/08009; G02B 6/124; G02B 5/1857; G02B 5/1861; G03F 7/20
USPC 372/102; 359/569; 430/321; 430/296

(57) ABSTRACT

Volumetric Bragg grating devices that operate in middle-infrared region of the spectrum and methods for producing such devices are described. Such a Volumetric Bragg grating device can be produced by forming a plurality of color centers within an alkali-halide crystal and selectively removing a subset of the plurality of color centers to produce variations in refractive index of the alkali-halide crystal in the middle-infrared spectral region and to thereby produce a volumetric Bragg grating that operates in middle-infrared spectral range.

### PRIORITY CLAIM AND RELATED PATENT APPLICATION

The present patent application claims priority and benefits of U.S. Provisional Patent Application No. 61/586,086 entitled “MIDDLE-INFRARED VOLUMETRIC BRAGG GRATING BASED ON LIF COLOR CENTER CRYSTALS” and filed Jan. 12, 2012, which is incorporated herein by reference.

### TECHNICAL FIELD

The present application generally relates to color center crystals for applications in volumetric Bragg gratings in the middle-infrared spectral range.

### BACKGROUND

Volumetric Bragg gratings (VBGs) can be implemented as Bragg gratings in bulk transparent materials in form of a periodic variation of the refractive index that interacts with incident light to produce a large reflectivity at one or more Bragg wavelengths that fulfill the Bragg condition. VBGs can be used in various optical devices and systems and are key elements for development of compact narrow line laser systems. Currently, many VBGs use photorefractive glasses with a transmission spectral range between 0.3 μm and 2.7 μm.

### SUMMARY

The disclosed embodiments relate to volumetric Bragg grating devices, and methods for fabricating such devices, that are based on Alkali-Halide crystals with color centers that operate in mid-IR region. Such devices can be implemented in ways so that they are photo-stable and thermally stable, and can be massed produced using relatively low power lasers.

One aspect of the disclosed embodiments relates to a volumetric Bragg grating device that comprises an alkali-halide crystal including a plurality of color centers with wide spectral transparency in mid-infrared spectral range. The alkali-halide crystal is structured to exhibit variations in refractive index of the alkali-halide crystal in mid-infrared spectral region through selective removal of at least a subset of the plurality of color centers to form a volumetric Bragg grating that operates in mid-infrared spectral range.

In one exemplary embodiment, the alkali-halide crystal is a Lithium Fluoride (LiF) crystal. In another exemplary embodiment, the alkali-halide crystal is structured by photo-induced bleaching of the subset of color centers. In yet another exemplary embodiment, the volumetric Bragg grating can exhibit efficiency in the range of approximately above 10 to nearly 100 percent within spectral range spanning approximately 1 to 6 micrometers. According to still another exemplary embodiment, the volumetric Bragg grating includes grooves or regions that are formed as spatial variations in the refractive index as a result of selective removal of the plurality of color centers.

In one exemplary embodiment, the selective removal includes photo-induced bleaching of the subset of the plurality of color centers. In another exemplary embodiment, the variation in refractive index is at least 10⁻⁴ in spectral region spanning approximately 1 to 6 micrometers. According to another exemplary embodiment, the plurality of color centers is formed within the alkali-halide crystal by ionizing radiation and/or additive or electrolytic coloration. In another exemplary embodiment, the volumetric Bragg grating is configured to operate as a reflector or an output coupler of a laser cavity. Another exemplary embodiment relates to a laser system that comprises the above noted volumetric Bragg grating, where the volumetric Bragg grating is configured to operate as a high reflector of a laser cavity of the laser system.

Another aspect of the disclosed embodiments relates to a method for producing a volumetric Bragg grating device that includes obtaining an alkali-halide crystal comprising a plurality of color centers, and selectively removing a subset of the plurality of color centers to produce variations in refractive index of the alkali-halide crystal in the mid-infrared spectral region and to thereby produce a volumetric Bragg grating that operates in mid-infrared spectral range.

In one exemplary embodiment, the alkali-halide crystal is a Lithium Flouride (LiF) crystal. According to another exemplary embodiment, the obtaining alkali-halide crystal comprising the plurality of color centers comprises exposing the alkali-halide crystal to an ionizing radiation and/or through additive or electrolytic coloration to form the plurality of color centers. In one exemplary embodiment, selectively removing the subset of the plurality of color centers comprises photo-induced bleaching of the subset of color centers. For example, the photo-induced bleaching can include (a) exposing the alkali-halide crystal comprising the plurality of color centers to a laser beam to form a first groove or region, (b) shifting the position of the alkali-halide crystal, (c) subsequent to the shifting, exposing the alkali-halide crystal to the laser beam form a second groove or region and (d) repeating steps (b) and (c) a predetermined number of times to form additional grooves or regions. The formed grooves or regions form a spatial periodic grating pattern. In one exemplary embodiment, selectively removing the subset of the plurality of color centers comprises directing two or more coherent optical beams to the alkali-halide crystal to cause formation of the volumetric Bragg grating using an interference pattern of the two or more beams.

According to one exemplary embodiment, selectively removing the subset of the plurality of color centers is carried out through an electron or ion beam lithography. In another exemplary embodiment, the variation in refractive index is at least 10⁻⁴ in spectral region spanning approximately 1 to 6 micrometers. In still another exemplary embodiment, selectively removing the plurality of color centers produces spatial variations in the refractive index that form a plurality of grooves or regions of the volumetric Bragg grating. In yet another exemplary embodiment, the volumetric Bragg grating can exhibit efficiency in the range from approximately 10 percent to nearly 100 percent within spectral range spanning approximately 1 to 6 micrometers. In another exemplary embodiment, the volumetric Bragg grating is a phase grating that effectuates diffraction of light at least 1.56 micrometers.

In addition, a method is provided for using a volumetric Bragg grating formed of an alkali-halide crystal with color centers is to diffract light in a mid-IR spectral range to produce optical reflection at a specific wavelength under the Bragg condition. In this method, under a room temperature, an alkali-halide color center crystal, which exhibits optical transparency in a middle-infrared spectral range and optical absorption in a visible or a near-infrared spectral range, is exposed to an incident optical beam in the middle-infrared spectral range. The alkali-halide color center crystal is structured to include a permanent spatial periodic grating pattern of color centers that has a sufficient spatial periodic modulation in a refractive index in the alkali-halide color center crystal in the middle-infrared spectral range to effectuate a phase Bragg grating. The orientation of the permanent spatial periodic grating pattern with respect to the incident optical beam is controlled to diffract light of the input optical beam under a Bragg condition to produce an optical reflection in the middle-infrared spectral range.

These and other aspects and embodiments are described in greater detail in the drawings, the description and the claims.

### BRIEF DESCRIPTION OF THE DRAWINGS

FIG. 1(a) is a UV-visible part of an exemplary absorption spectrum of a LiF crystal sample with color centers.

FIG. 1(b) is a visible-near-IR part of an exemplary absorption spectrum of a LiF crystal sample with color centers.

FIG. 2(a) is an example of the UV-near-IR part of theoretically calculated (per Equation (4)) plot of variations in index of refraction as function of wavelength for a LiF crystal. Black dashed curve takes into account all color centers in the sample. The solid curve takes into account only absorption of two major bands (F and F₂& F₃).

FIG. 2(b) is an example of the near-middle-IR part of theoretically calculated (per Equation (4)) plot of variations in index of refraction as function of wavelength for a LiF crystal. The solid curve takes into account only absorption of two major bands (F and F₂& F₃).

FIG. 3 illustrates a configuration for fabrication of a VBG in accordance with an exemplary embodiment.

FIG. 4 illustrates photoluminescence (PL) spectra of a LiF CC crystal measured under 514 nm Argon laser excitation before and after irradiation with a Ti-Sapphire laser (790 nm, 400 mW, 1 kHz, 35 fs, 5 second exposition) in accordance with an exemplary embodiment. Plot (a) corresponds to PL spectrum before irradiation, plot (b) corresponds to PL spectrum immediately after irradiation taken from the area of the crystal adjacent to the bleached stripe, plot (c) corresponds to PL spectrum immediately after irradiation taken from the bleached stripe area of the crystal, and plot (d) corresponds to the PL spectrum of the bleached stripe approximately 12 hours after laser irradiation.

FIG. 5(a) illustrates variations in measured integral 650-700 nm photoluminescence intensity as a function of distance from the beginning of a grating with a 12-μm groove spacing shortly after fabrication in accordance with an exemplary embodiment.

FIG. 5(b) is a portion of FIG. 5(a) that is zoomed-in to illustrate photoluminescence intensity variations at a distance between 500 to 600 μm from the beginning of the grating.

FIG. 5(c) illustrates variations in measured integral 650-700 nm photoluminescence intensity as a function of distance from the beginning of the a grating characterized in FIG. 5(a) about 12 hours after fabrication in accordance with an exemplary embodiment.

FIG. 5(d) is a portion of FIG. 5(c) that is zoomed-in to illustrate photoluminescence intensity variations at a distance between 500 to 600 μm from the beginning of the grating.

FIG. 6(a) illustrates variations in measured integral 650-700 nm photoluminescence intensity as a function of distance from the beginning of a grating with a 24-μm groove spacing shortly after fabrication in accordance with an exemplary embodiment.

FIG. 6(b) is a portion of FIG. 6(a) that is zoomed-in to illustrate photoluminescence intensity variations at a distance between 500 to 600 μm from the beginning of the grating.

FIG. 6(c) illustrates variations in measured integral 650-700 nm photoluminescence intensity as a function of distance from the beginning of the grating characterized in FIG. 6(a) about 12 hours after fabrication in accordance with an exemplary embodiment.

FIG. 6(d) is a portion of FIG. 6(c) that is zoomed-in to illustrate photoluminescence intensity variations at a distance between 500 to 600 μm from the beginning of the grating.

FIG. 7 illustrates a configuration for characterizing the grating in accordance with an exemplary embodiment.

FIG. 8 illustrates a set of operations that may be carried out to produce a volumetric Bragg grating in accordance with an exemplary embodiment.

FIG. 9 illustrates a set of operations that may be carried out for using a volumetric Bragg grating formed of an alkali-halide crystal with color centers to diffract light in a mid-IR spectral range to produce optical reflection in accordance with an exemplary embodiment.

### DETAILED DESCRIPTION OF CERTAIN EMBODIMENTS

Color center (CC) is a point lattice defect within a crystal that produces optical absorption bands in an otherwise transparent crystal. Alkali-halide crystals with color centers (CCs) have been known as active media for tunable solid state lasers and as passive Q-switches for many years. Among different alkali-halide crystals, Lithium Fluoride (LiF) is a commonly used material, in-part because it is not hygroscopic and features high stability of the CCs even at room temperature. Recent research interest has shifted to possible photonics applications of these materials that are based on their photorefractive properties. Some of these applications are based on fabrication of photo-induced gratings and waveguides in the crystals with color centers.

Recent progress in room temperature mid-IR lasers operating over 2-6 μm stimulates development of new photorefractive materials for these lasers, as VBGs that are fabricated using photorefractive glasses are incapable of operating in the mid-IR region.

Photorefractive materials operating in the middle-infrared (mid-IR) spectral range are important for development of new compact mid-IR laser systems with many potential applications. Examples of such applications include, but are not limited to, molecular spectroscopy, non-invasive medical diagnostics, industrial process control, environmental monitoring, atmospheric sensing, free space communication, oil prospecting, and numerous defense related applications such as infrared countermeasures, monitoring of munitions disposal, and stand-off detection of explosion hazards.

Alkali-Halide crystals such as Lithium Fluoride (LiF) crystals have wide transparency in the mid-IR region. However, attempts to fabricate VBGs from such Alkali-Halide crystals are not commercially feasible. This is partly due to a need for irradiating the crystals with high intensity femstosecond laser radiation in order to inscribe permanent modification to the crystal structure to cause variations in the index of refraction of the crystal.

Color Center Lasers with distributed feedback (DFB) have been studied by several research groups. Tunable laser oscillation of LiF with F₂⁺ CCs has been achieved in the near-IR region 882-962 nm and a dynamic gain grating in the crystal has been realized using the interference of two pump beams. In some systems, tuning of the DFB laser has been obtained by changing the incident angle of the pumping beams. In some systems, DFB CC lasing with permanent grating is obtained through a gain element that is developed by photo-bleaching of the color center based on interference pattern formed by a UV laser. In one system, a permanent grating is fabricated by a holographic technique based on utilization of two femtosecond Ti:sapphire laser beams, producing distributed feedback laser oscillation of LiF:F₂ CC crystal at 709 nm.

Various investigations conducted so far have been focused on the photorefractive properties in CC crystals (CCCs) in the visible and near-IR spectral range, where the change of the refractive index is significant and is, in some cases, near or at maximum values for the change of the refractive index. LiF has a wide transmission band and can potentially operate at mid-IR wavelengths up to 6 μm. Various LiF:CC crystals prepared by ionizing irradiation or additive/electrolytic coloration exhibit strong absorption bands in the visible and near-IR spectral range. In such crystals, spatially selective color center photo-bleaching of the color centers can be used to produce a spatial pattern or modulation in the refractive index of the LiF crystal. At each location where the color centers are photo bleached, the color centers are removed so that the location no longer exhibits optical absorption of the particular color center that has been photo bleached. LiF:CC crystals tend not to have strong absorption bands in the mid-IR spectral range. Since strong absorption bands are generally associated with significant changes in value of the refractive index, this lack of strong absorption bands in the Mid-IR spectral range in LiF:CC crystals has been perceived as inability of LiF:CC crystals to provide significant index changes for forming volumetric Bragg grating (VBG) structures with usable grating diffraction efficiency in the Mid-IR spectral range. Moreover, LiF:CC crystals have been perceived as having thermal and photo-induced instabilities and thus are unsuitable for applications and uses at day light and ambient or room temperatures.

The LiF:CC crystals and other alkali-halide crystals with CCs, however, can be engineered to have unique properties that are attractive and desirable for operations in the Mid-IR spectral range. For example, LiF CCCs made from hydroxyl free LiF crystals feature large (˜14 ev) bandgap, don't exhibit shallow donor and acceptor CCs and, hence, don't have absorption of light in the mid-IR spectral range. As a result, there tends to be no photo-bleaching of color centers when the crystal is under illumination of light in the mid-IR spectral range. Therefore, LiF:CC volumetric Bragg grating (VBG) structures are stable under high optical density mid-IR irradiation. For another example, LiF crystals tend to exhibit wide transparency bands (e.g., including the mid-IR spectral range up to 6 μm) and can be used as dispersive elements for Er³⁺, Ho³⁺, Tm³⁺ Cr²⁺, Fe²⁺ lasers operating over a spectral range from 1.5 μm to 6 μm. Notably, as illustrated by the exemplary embodiments described below, despite lack of strong absorption bands in the Mid-IR spectral range in LiF:CC crystals, they can be structured to exhibit sufficient changes in the refractive index to provide stable and efficient volumetric Bragg grating (VBG) structures in the Mid-IR spectral range for various applications. Under the Bragg condition for a VBG for incident light at or around the Bragg wavelength, even a weak index modulation in the crystal can be sufficient for achieving a relatively large optical reflection such as retro-reflection. Therefore, LiF-based gratings are attractive in filling a needed void in part because various commonly used VBGs fabricated from glass materials cannot operate efficiently at various mid-wavelengths, e.g., at wavelengths longer than 3 μm.

The disclosed embodiments demonstrate the feasibility of CCCs as media for VBG devices operating in the mid-IR spectral range. Color centers in LiF:CC crystals can be bleached or removed at selected spatial locations by photo-bleaching or other bleaching techniques to produce spatially periodic modulations in the refractive of index in the crystal that are sufficient to effectuate VBGs for the mid-IR spectral range in which LiF:CC crystals are optically transparent and do not exhibit strong optical absorption. According to some embodiments, diffractive gratings are fabricated in LiF:CC crystals by photo-induced bleaching of the CCs and characterized at 0.532 μm, 0.632 μm and 1.56 μm. Further, the methodology of the disclosed embodiments related to photorefractive effect based on color center bleaching can provide VBG efficiencies in the range from about 10% to nearly 100%, which is sufficient for various photonic applications, such as for operating an optical coupler or high reflector of a laser cavity. In one exemplary embodiment, an efficiency of approximately 60% can be achieved for 1-3 cm long crystals in at least the 1-6 μm spectral range covering the mid-IR spectral range. Diffraction efficiency is a measure of how much optical power is diffracted into a designated direction compared to the power incident onto the diffractive element.

It should be noted that LiF crystals and LiF:CCCs are used as examples in this document to illustrate the principles of the disclosed embodiments. Various technical features described in this document are applicable to and relevant to other alkali-halide crystals with color centers.

As an initial matter, changes of the refractive index in the LiF induced by CCs are considered. Propagation of radiation in the absorptive media is characterized by complex refractive index ñ and defined by the Equation (1):

ñ=n+iκ (1)

In Equation (1), n and κ are real and imaginary parts of the complex refractive index, respectively. The imaginary part of the refractive index is responsible for decay of the intensity of the radiation during propagation in the media and could be expressed using absorption coefficient (α) as follows:

$$k = \frac{4 n α}{λ} \qquad ( 2 )$$

In Equation (2), λ is free space wavelength. The real and imaginary parts of the refractive index can be related by the Kramers-Kronig Relations, as provided by Equations (3a) and (3b):

$$\begin{matrix}Δ n ( ω ) = \frac{1}{π} P {\int }_{- ∞}^{+ ∞} \frac{κ ( {ω}^{′} )}{{ω}^{′} - ω} d {ω}^{′} & ( 3 a ) \\ κ ( ω ) = - \frac{1}{π} P {\int }_{- ∞}^{+ ∞} \frac{n ( {ω}^{′} ) - 1}{{ω}^{′} - ω} d {ω}^{′} , & ( 3 b )\end{matrix}$$

In Equations (3a) and (3b), Δn is refractive index change induced by absorption κ(ω) as a function of complex variable ω, and P is the Cauchy principal value. Although, the change of the refractive index in the Alkali-halide crystals due to CC absorption has been studied, such studies have been focused on the near-IR and visible spectral ranges. Numerical calculations have been conducted in accordance with the disclosed embodiments to quantify refractive index changes induced by CCs absorption bands. Based on these calculations, the strongest absorption line of the CCs crystal belongs to the F-centers. An F-center is an anionic vacancy that is filled by a single-electron. It is the simplest CC in the crystals with the highest concentration compared to other possible CCs. In LiF crystals, the absorption band of the F-CCs is located at 248 nm, and the absorption coefficient can reach 1000 cm⁻¹ in a highly irradiated crystal. Using this value for α(ω) and the Kramers-Kronig relations, Equation (3a) estimates the refractive index change using:

$$Δ n = \frac{{α}_{0} {λ}_{0}}{4 π} \frac{( 2 ( ω - {ω}_{0} ) / Δω )}{1 + {( 2 ( ω - {ω}_{0} ) / Δω )}^{2}} \qquad ( 4 )$$

In Equation (4),

$${α}_{0} = \frac{{κ}_{0} {λ}_{0}}{4 n}$$

is a maximum absorption coefficient and Δω is a Full-Width-Half-Maximum (FWHM) of the absorption line. The maximum value of Δnₘₐₓ is equal to Δnₘₐₓ=1/2κ₀ at ω=ω₀±Δω/2, and for low frequency limit ω<<Δω<ω₀, the change of the refractive index is:

$$Δ n ( 0 ) = \frac{{α}_{0} {λ}_{0}}{4 π} \frac{Δω}{2 {ω}_{0}} = {n}_{max} \frac{Δω}{{ω}_{0}} \qquad ( 5 )$$

For the most fundamental F-band in LiF color center crystal (i.e., λ₀=248 nm, Δf_{FWHM}/f₀=0.155) and absorption coefficient of α₀=500 cm⁻¹, the estimated Δnₘₐₓ=5×10⁻⁴ and Δn(0)=0.8×10⁻⁴.

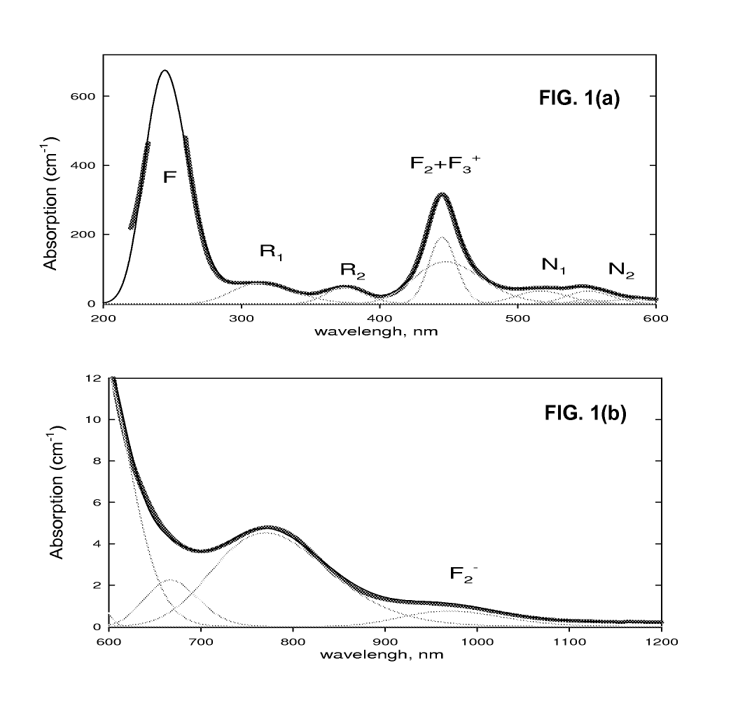

It should be noted that the CC absorption bands are better approximated by Gaussian shape due to a strong electron-phonon coupling. This requires a numerical calculation of Cauchy's integral in Equation (3a). For these calculations that are carried out based on the disclosed embodiments, absorption coefficients of the prepared samples with different thicknesses (from hundreds of micron to several mm) are measured to increase accuracy of measurement of absorption coefficients of different CCs. The experimental data of the absorption spectra are shown in FIGS. 1(a) and 1(b) as a thick solid line. FIG. 1(a) illustrates the absorption spectra in the UV-visible region, while FIG. 1(b) illustrates the absorption spectra in the visible-near IR region. Due to a relatively high absorption coefficient, direct measurements of the maximum of the F-band could not be measured. However, the maximum of the F-band can also be estimated from the band shape and position of the maximum measured from the low irradiated samples. For refractive index calculations, the measured absorption spectra in the frequency domain were fitted using Gaussian absorption bands of the F center and 10 other aggregate CCs. The fitting results (i.e., absorption spectrum deconvolution by Gaussian bands) are shown as thin curves in FIGS. 1(a) and 1(b) and summarized in the Table 1. In Table 1, α is the absorption coefficient, λ₀ is maximum of the absorption band, C/F₀ is the position of the maximum of the band and W/F₀ is FWHM normalized to the frequency of the position of the F band.

| CC (λ₀, nm) | α (cm⁻¹) | C/F₀ | W/F₀ |
|---|---|---|---|
| F₂⁻(969) | 0.75 | 0.26 | 0.015 |
| N₁⁻(775) | 4.53 | 0.32 | 0.026 |
| N₄(667) | 2.25 | 0.37 | 0.016 |
| N₃(592) | 12.69 | 0.42 | 0.021 |
| N₂(551) | 36.08 | 0.45 | 0.013 |
| N₁(516) | 36.65 | 0.48 | 0.017 |
| F₃⁺(447) | 121.01 | 0.55 | 0.030 |
| F₂(445) | 192.67 | 0.56 | 0.012 |
| F₃, R2 (375) | 46.0 | 0.66 | 0.025 |
| F₃, R1 (314) | 59.5 | 0.79 | 0.055 |
| F(248) | 674.72 | 1.01 | 0.065 |

The most dominant bands are F band at 248 nm with absorption coefficient 675 cm⁻¹ and band at 450 nm which results from overlapping of the F₂ and F₃⁺ bands with a total absorption coefficient equal to 314 cm⁻¹.

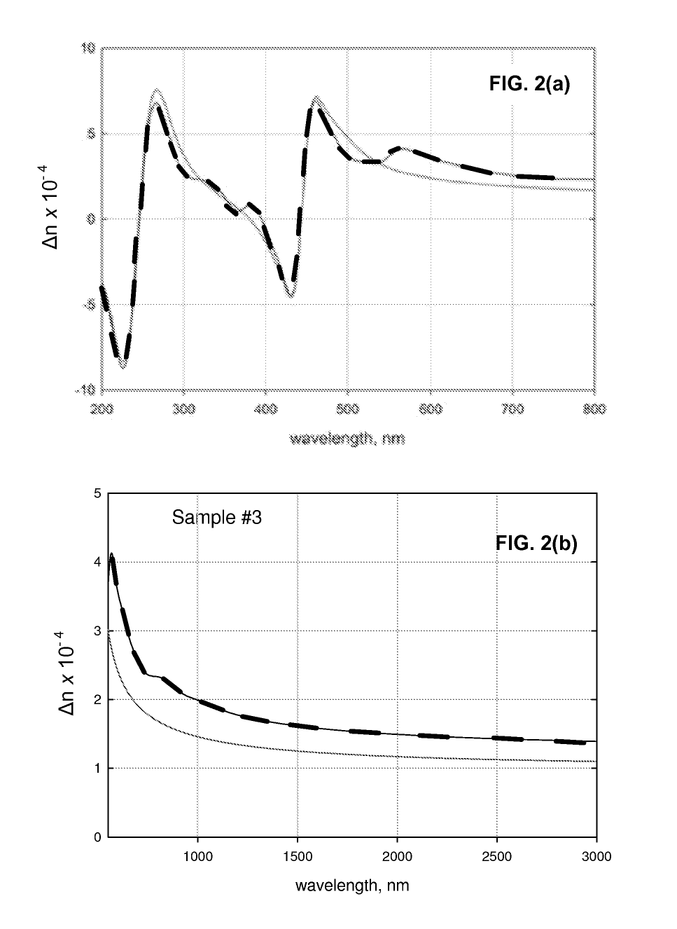

Calculation of the refractive index change using Equation (3a) can be performed with custom-designed and/or commercially available software, such as MAPLE 4 software, and compared to the analytical solution for the Lorentz bands. The absorption index changes induced by color centers are shown in FIGS. 2(a) and 2(b). The dashed curve represents the results for Δn induced by all color centers in the sample and the solid curve represents the results only for absorption only by two major bands (F and F₂/F₃⁺ combination). As evident from the plots, Δn≧10⁻⁴ can be obtained in the near-mid-IR spectral range (i.e., at least in the range 1000-3000 nm and up to 6000 nm). Consideration of only two major absorptions bands at 248 and 450 nm (F and F₂/F₃⁺ combination) reduces the Δn calculated value only by 30%.

Therefore, while LiF CCs don't have absorption in the mid-IR spectral range, selective removal or bleaching of the color centers can result in a refractive index change Δn of at least 10⁻⁴ over near- to mid-IR spectral range. As a result, LiF CCCs can be used as photorefractive media for narrowband mid-IR Bragg reflectors.

Λn optical Volumetric Bragg Grating (VBG) is a device with a periodic variation of the refractive index. The reflected wavelength, λ, can be determined under the Bragg condition as follows:

λ=2nΛ (6)

In Equation (6), n is the effective refractive index of the grating and Λ is the period. The reflection efficiency can be estimated using the following equation:

$$η = {[ tanh ( \frac{π L}{λ} ( Δ n ) ) ]}^{2} \qquad ( 7 )$$

In Equation (7), L is the length of the periodic structure. Equation (7) can be used to obtain a desired grating efficiency as a function of the length of the grating and the change in refractive index to fit the needs of a particular photonic system or application. For example, the required length of the periodic structure with R=60% can be found using:

$$\frac{π L}{{λ}_{0}} ( δ n ) \approx 1 \qquad ( 8 )$$

Using Δn˜10⁻⁴, the required length of the diffraction grating, L, is 0.5 to 1 cm for λ₀ of 1.5 to 6 μm. Current technology enables fabrication of homogeneously colored LiF crystals with typical sizes over 10 cm. In accordance with the disclosed embodiments, efficiencies in the range from about 10% to nearly 100% can be achieved, which is sufficient for most, if not all, practical optical applications. The grating with 0.5 to 3 μm period and 1 cm length can be fabricated using various methods, such as a holographic method or direct e-beam writing.

In accordance with an exemplary embodiment, to produce CCs, LiF crystals (e.g., 5×5×5 mm³ crystals) were γ-irradiated at 300 K with a dose of 2×10⁸ rad using a ⁶⁰Co source. After irradiation, one sample was cleaved and polished to prepare crystals with different thicknesses for absorption measurements. The absorption spectra were obtained using a Shimadzu UV3101-PC spectrophotometer. The amplified Ti:sapphire laser used was a Coherent Legend Elite producing 3.5 W of average power with a ˜35 fs duration at a repetition rate of 1 kHz to selectively remove a subset of the color centers.

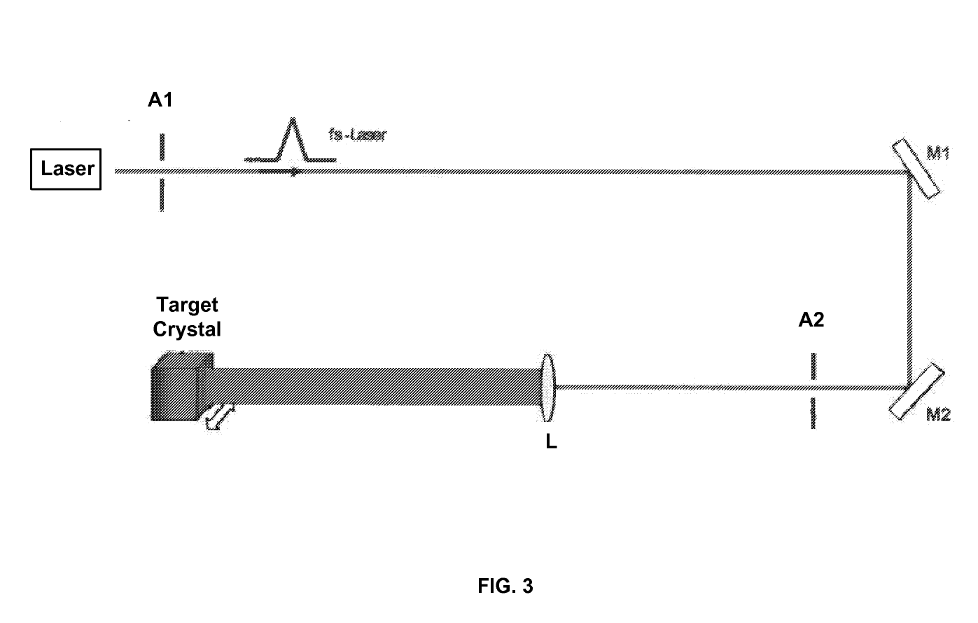

FIG. 3 illustrates a configuration for fabrication of the VBG in accordance with an exemplary embodiment. To selectively remove the color centers and fabricate the grating, radiation from a laser is incident upon a first M1 and a second mirror M2 and is focused by a lens, L, on the target crystal, such as a LiF crystal to form a focused optical beam in form of a band or strip. This focused optical band or strip produces a sufficient local optical intensity to cause optical bleaching or remove of the color centers. The focused optical beam and the crystal are moved relative to each other to optically bleach a series of such bands or strips to form a desired grating pattern. As evident from the exemplary configuration of FIG. 3, one or more apertures, such as apertures A1 and A2, can be placed in the optical path of the laser beam. In one exemplary embodiments, a Ti:sapphire laser with average power 400 mW and 1 cm beam diameter is focused by a cylindrical lens with 15 mm focal distance on a LiF crystal surface. The crystal can be mounted on a computer controlled translational stage to allow movement of the crystal relative to the incident laser beam in order to obtain periodic spacing. The movement can be programmed using, for example, Thorlabs APT System software. In one exemplary embodiment, one site on the target crystal is irradiated for 5 seconds to produce one groove or region (i.e., a bleached stripe). The target crystal is then shifted 12 μm or 24 μm by using a motorized translation stage to expose another section of the target crystal to laser radiation to produce a second groove or region. This procedure can be repeated as many times as necessary to product a desired number of grooves or strip regions with a desired spacing. In one example embodiment, this procedure was repeated 100 times to produce 100 grooves in each grating. In one experiment, two gratings were created, one with 12 μm and the other with 24 μm period (or spacing), respectively. Therefore, VBGs that are produced based on the disclosed techniques can be fabricated using relatively low power laser radiation in a simple configuration that allows mass production of such VBGs economically and practically feasible.

In one exemplary embodiment, diffraction gratings were characterized by Confocal Micro-Raman System (Horiba Jobin Yvon, LabRam HR) equipped with 800-mm focal length spectrometer (HR 800 UV), optimized for the 200-1600 nm spectral region, thermoelectrically cooled CCD camera, and X-Y translation stage with 100 nm precision. A λ=514 nm Argon-Ion laser with approximately 100 μW of incident power at the sample was used for photoluminescence experiments. The lateral resolution of the Micro-Raman System was ˜1 μm. The sample was scanned across gratings using translation stage with 1 μm step size and the signal was accumulated for 0.5 s at each position. The photoluminescence integral intensity of F₂ CC in 650-700 nm spectral window was used as a method to estimate the CC concentration and gratings quality. Photoluminescence mapping was performed immediately after gratings were produced and after 12 hours for each grating. The diffraction grating efficiencies were characterized at normal incidence using CW radiation of the second harmonic of the Nd:YAG (0.532 μm), He—Ne (0.632 μm), and Er-fiber (1.56 μm) lasers. Fabrication procedure of a volumetric Bragg grating in LiF CCCs can be also based on other methods of modification of absorption coefficient and refractive index. Among these methods, holographic grating writing based on interference pattern of the optical beams can be used to produce the spatial patterns for the volumetric Bragg grating. The method utilizes modification of the refractive index in pure LiF crystal subjected to irradiation with short optical pulses. Another approach uses CCs degradation in the nodes of the interference pattern. Bragg gratings in LiF CCCs can also be directly written by electron or ion beam lithography, or done via thermal bleaching.

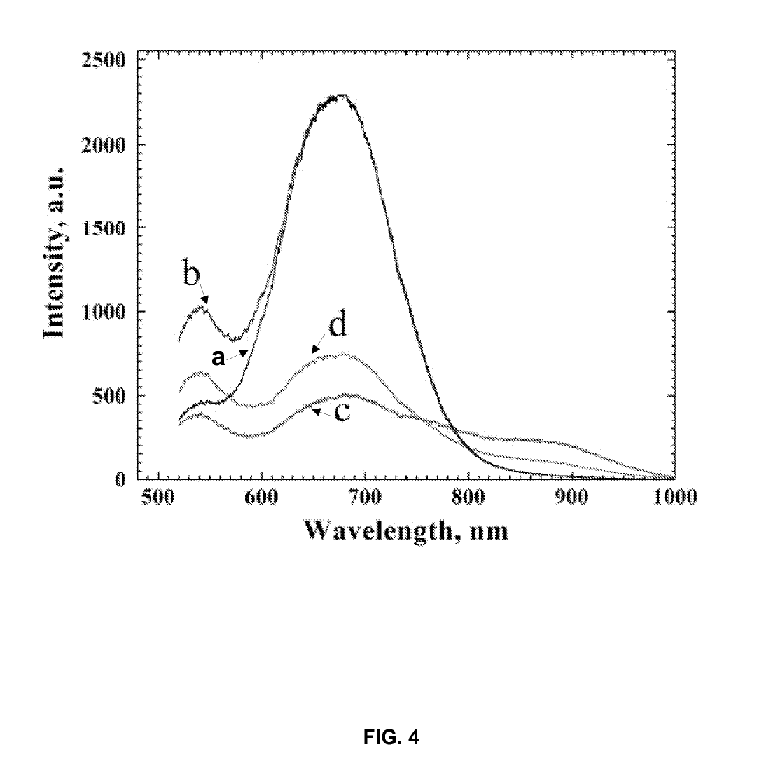

FIG. 4 shows the photoluminescence (PL) spectra of a LiF CC crystal before and after Ti:sapphire laser irradiation. The PL spectra that are shown in FIG. 4 were measured under excitation by Argon laser at 514 nm. The PL spectrum of the sample before fs-irradiation (i.e., the plot labeled ‘a’) consist of F₂ and F₃⁺ bands with maxima at 670 nm and 530 nm, correspondingly. The exposure to fs laser radiation produced bleached areas (i.e., stripes or grooves of diffraction grating) that were clearly visible to the eye. In FIG. 4, the plot labeled ‘b’ represents PL spectrum associated with the area of the crystal adjacent to the bleached areas. The color of bleached areas changed from brown to light green indicating ionization of F₂ color centers. In FIG. 4, the plot labeled ‘c’ corresponds to the PL spectrum of the bleached areas. Plot ‘c’ demonstrates substantial decrease in signal intensity in 600-800 nm spectral range corresponding to PL of F₂ CC and appearance of new band around 900 nm corresponding to PL of F₂⁺ CC. The F₂⁺ CCs are unstable at room temperature and disappear after approximately 12-24 hours. The plot labeled ‘d’ in FIG. 4 corresponds to PL spectrum of bleached areas after 12 hours. Plot ‘d’ indicates that the intensity of the PL band at 900 nm decreases and the PL band intensity of F₂ CC slightly recovers after approximately 12 hours.

It should be noted that the LiF:CC crystals used for conducting experimentation were more than 15 years old. Further, while the exemplary measurements that are shown correspond to measurements immediately after, and measurements approximately 12 hours after, irradiation of the LiF:CC crystal with the Ti:Sapphire laser, the produced VBGs exhibited stability well beyond the 12-hour period, and are expected to remain stable for many years thereafter. Therefore, the VBGs that are produced in accordance with the disclosed embodiments can not only be mass-produced using fabricated using low power radiation femtosecond laser pulses, but they also exhibit photo stability and thermal stability.

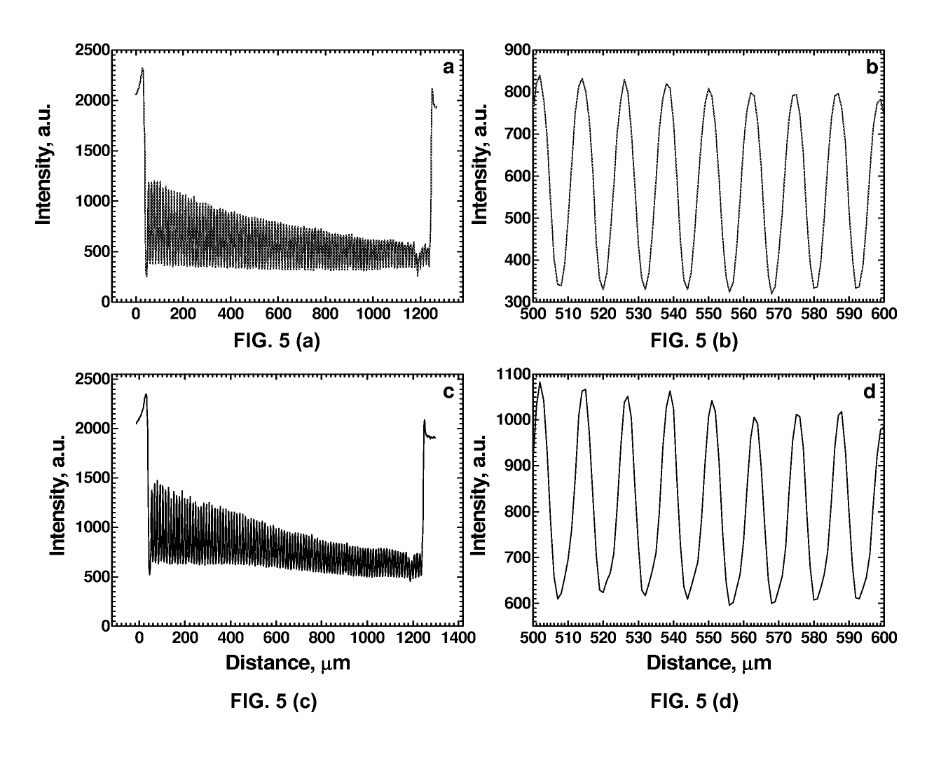

The photoluminescence imaging of a LiF CC crystal fabricated in accordance with an exemplary embodiment with 84 grooves/mm diffraction gratings (which corresponds to approximately a 12 μm period) are shown in FIGS. 5(a) to 5(d). To produce the intensity plots in FIGS. 5(a) to 5(d), scanning of the gratings was done using an X-Y translation stage with 100 nm precision and 1 μm lateral resolution of the Confocal Micro-Raman System. FIGS. 5(a) to 5(d) show that for a 84 grooves/mm grating, the caustic of the Ti:sapphire laser beam after focusing by 15 mm cylindrical lens is sufficient to produce a grating with a sufficient contrast. In particular, FIG. 5(a) illustrates variations in the measured intensity as a function of wavelength shortly after fabrication of the grating. FIG. 5(b) is a zoomed-in version of FIG. 5(a) to provide a better view of the measured intensity in the spectral range 500-600 μm. FIG. 5(c) illustrates variations in measured intensity as a function of wavelength 12 hours after fabrication of the grating. FIG. 5(d) is a zoomed-in version of FIG. 5(c) to provide a better view of the measured intensity in the spectral range 500-600 μm. The plots in FIGS. 5(a) and 5(c) exhibit an intensity decrease as a function of wavelength, which is due to poor parallelism of the crystal surfaces that results in defocus of the microscope during scanning over the lateral 1.2 mm distance. The PL signal intensity slightly increased after 12 hours compared to initial observations.

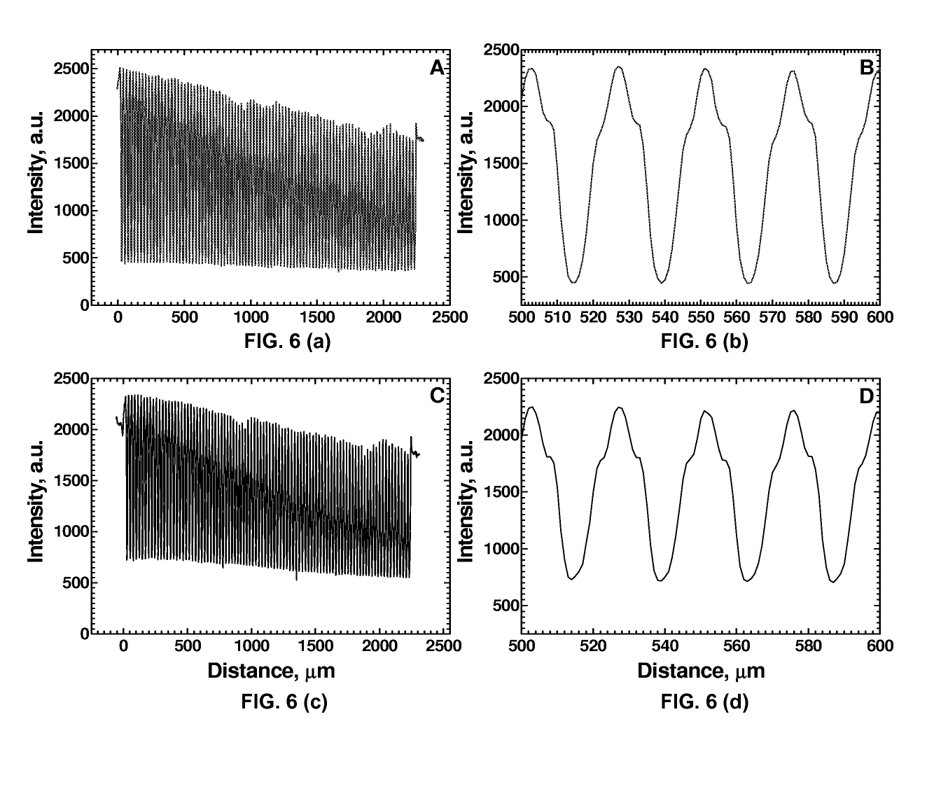

FIGS. 6(a) to 6(d) illustrate photoluminescence imaging results for a LiF CC crystal fabricated in accordance with an exemplary embodiment with 42 grooves/mm diffraction gratings (which corresponds to approximately a 24 μm period). In particular, FIG. 6(a) illustrates variations in the measured intensity as a function of wavelength shortly after fabrication of the grating. FIG. 6(b) is a zoomed-in version of FIG. 6(a) to provide a better view of the measured intensity in the spatial range 500-600 μm from the beginning of the grating. FIG. 6(c) illustrates variations in the measured intensity as a function of wavelength 12 hours after fabrication of the grating. FIG. 6(d) is a zoomed-in version of FIG. 6(c) to provide a better view of the measured intensity in the spatial range 500-600 μm from the beginning of the grating. Similar to the plots in FIGS. 5(a) and 5(c), FIGS. 6(a) and 6(c) illustrate a defocus for the 42 grooves/mm grating, as evident from gradual intensity decrease as a function of wavelength, with an improved grating contrast, as expected.

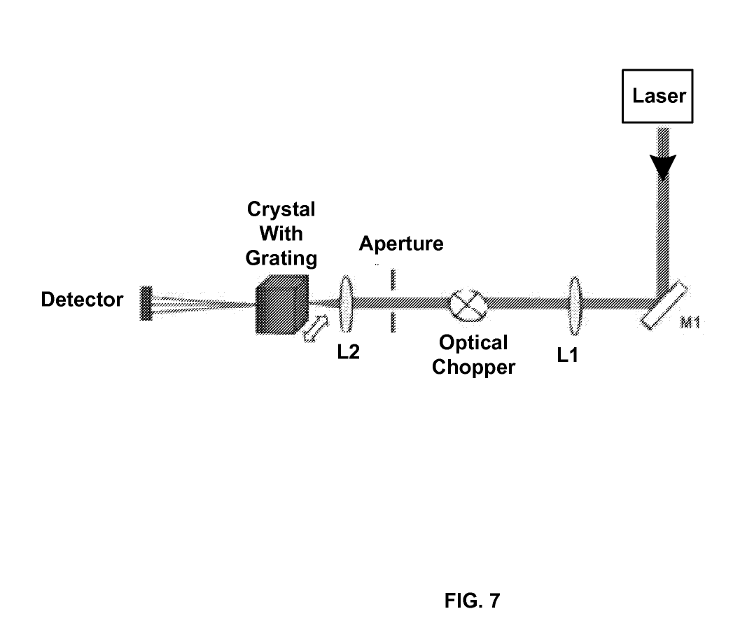

Diffraction grating efficiencies were characterized at normal incidence using three different CW lasers. In these experiments, the efficiency of Raman-Nath diffraction was measured to the first order at normal incidence. The laser beams were slightly focused on the grating surfaces to ensure a beam size smaller than grating size. One or more calibrated neutral filters were also used to increase the dynamic range of the photo-detectors. FIG. 7 shows a configuration for characterizing the grating in accordance with an exemplary embodiment. The light from the laser is incident on mirror, M1, and is directed to the crystal that includes the grating by propagating through a first lens, L1, an optical chopper, and a second lens, L2. The diffracted light that propagates through the crystal is captured by a detector.

Using the configuration in FIG. 7, diffraction pattern of the second harmonic of a Nd:YAG (0.532 μm) as well as a He—Ne (0.632 μm) laser can be imaged at the detector. For example, at least 3 diffraction orders were imaged at normal incidence. The positions of the diffraction orders were in agreement with diffraction grating equation and grating periods measured from the previous experiments. The diffraction efficiencies at 0.532 μm were approximately equal to 2-3% for both gratings with periods of 12 and 24 μm. At 0.632 μm wavelength, the measured efficiency for the 24 and 12 μm gratings were approximately equal to 5% and 1%, respectively. It is noteworthy that for visible spectral range, the induced amplitude grating efficiency will prevail over a phase grating efficiency. To demonstrate feasibility of the mid-IR applications of the phase grating in the LiF crystals with CCs, diffraction efficiency was measured using Er-fiber laser operating at 1.56 μm. The measured efficiencies were approximately two-orders of magnitude smaller than in visible spectral range and were equal to 2×10⁻⁴ and 5×10⁻⁴ for the 24-μm and 12-μm gratings, respectively.

These measurements enable an estimation of the induced Δn at 1.56 μm. In particular, first-order Raman-Nath diffraction can be calculated using:

$${η}_{1} = {J}_{1}^{2} ( 2 \vert k \vert l ) = {J}_{1}^{2} ( πΔ n \frac{{l}_{G}}{λ} ) \approx {( kl )}^{2} = {( πΔ n \frac{{l}_{G}}{λ} )}^{2} \qquad ( 9 )$$

In Equation (9), J₁ is the Bessel function of order 1 and l_{G} is the thickness of the diffraction grating. The grating thickness can be estimated from the overlapping of writing beams propagating in the crystal. In one exemplary embodiment, a grating with 12-μm period is fabricated with an estimated pump beam width near crystal surface of approximately W_{b}≈7 μm. There are two major factors that are limiting the depth of the photo-induced grating. The first factor is beam divergence, which results in decreasing of the radiation flux. The second factor is spatial overlap of adjacent lines. The divergence (θ_{b}) of the writing beams separated by W_{G} distance overlaps at a distance l_{G}˜(W_{G}/2θ_{b})≈(W_{G} W_{b}/2_{λ}). For a grating with W_{G}=12 μm, the thickness of the diffraction grating is approximately l_{G}=50 μm. In an exemplary embodiment with a 24 μm period grating, the beams overlap at twice the distance and result in a greater diffraction efficiency, which was observed in the experiments conducted in accordance with the disclosed embodiments. The change of the refractive index calculated from experimental results was Δn≈10⁻⁴, which is close to the estimate. In one exemplary embodiment, the LiF crystal was exposed to mid-IR radiation of fiber laser with an average power of up to 15 W to directly show the feasibility of these diffraction gratings for applications of LiF CC crystals in mid-IR laser devices.

LiF Color Center crystals that are produced in accordance with the disclosed embodiments can be used for VBG operating in mid-IR spectral range and can provide efficiencies in the range from about 10% to nearly 100%. In one example, photorefractive effect based on color center bleaching can provide VBG efficiencies of approximately 60% in 1-6 μm spectral range for 0.5-2 cm long VBGs. Based on conducted test results, periodic structures with 24 and 12 μm periods in LiF:CCs were fabricated by using a femtosecond Ti:sapphire laser and were characterized using Raman-Nath diffraction at 0.532, 0.632, and 1.56 μm. Diffraction at 1.56 μm is a clear demonstration of phase grating fabrication and feasibility of these materials for mid-IR VBG applications. The measured induced change of the refractive index (Δn) was approximately 10⁻⁴, which is close to the estimated value and sufficient for VBG applications.

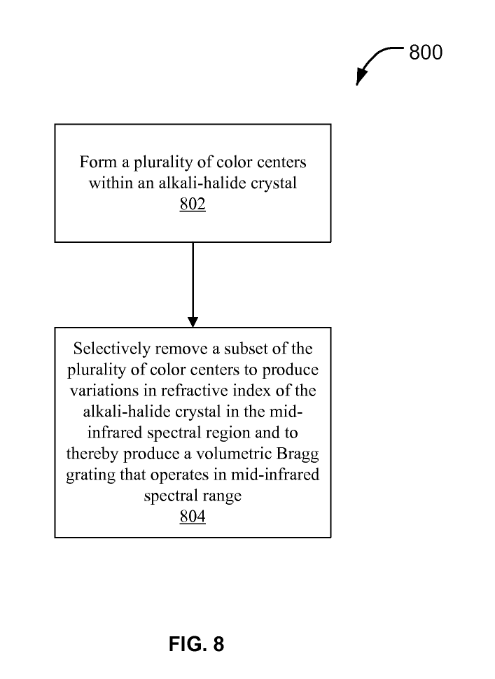

FIG. 8 illustrates a set of operations 800 that may be carried out to produce a volumetric Bragg grating in accordance with an exemplary embodiment. At 802, a plurality of color centers within an alkali-halide crystal are formed. Forming such color centers can, for example, be carried out by exposing the alkali-halide crystal to an ionizing radiation and/or through additive or electrolytic coloration. At 804, a subset of the plurality of color centers are removed to produce variations in refractive index of the alkali-halide crystal in the mid-IR spectral region and to thereby produce a volumetric Bragg grating that operates in mid-IR spectral range. Selective removal of the color centers can be done through, for example, photo-induced bleaching, an interference pattern of two coherent beams directed at the crystal, or direct write by electron or ion beam lithography.

Hence, based on the described techniques, a volumetric Bragg grating device for operating in a mid-infrared spectral range can be formed by using an alkali-halide crystal including a plurality of color centers with wide spectral transparency in a mid-infrared spectral range. The alkali-halide crystal is structured to exhibit variations in a refractive index of the alkali-halide crystal in the mid-infrared spectral range through selective removal of at least a subset of the plurality of color centers to form a volumetric Bragg grating that operates in the mid-infrared spectral range. In some applications, a volumetric Bragg grating device for diffracting light of a mid-IR spectral range can include an alkali-halide color center crystal that has no absorption bands in a mid-IR spectral range and has strong absorption bands in visible and near-IR spectral ranges where a phase Bragg grating is formed in the alkali-halide color center crystal that effectuates diffraction of light in the mid-IR spectral range. A method for fabricating a volumetric Bragg grating device for diffracting light in a mid-IR spectral range can also be implemented to include exposing an alkali-halide crystal to a radiation to produce color centers in the crystal which has no absorption bands in a mid-IR spectral range and has strong absorption bands in visible and near-IR spectral ranges, and writing a phase Bragg grating in the alkali-halide color center crystal which has a sufficient change in a refractive index in the alkali-halide color center crystal in the mid-IR that effectuates diffraction of light in the mid-IR spectral range. In one implementation of this method, an optical beam is directed to the alkali-halide color center crystal to cause formation of the phase Bragg grating in the alkali-halide color center crystal. In another implementation, two coherent optical beams are directed to the alkali-halide color center crystal to form an optical interference pattern which causes formation of the phase Bragg grating in the alkali-halide color center crystal. In yet another implementation, an electron or ion beam lithography is performed on the alkali-halide color center crystal to write the phase Bragg grating in the alkali-halide color center crystal.

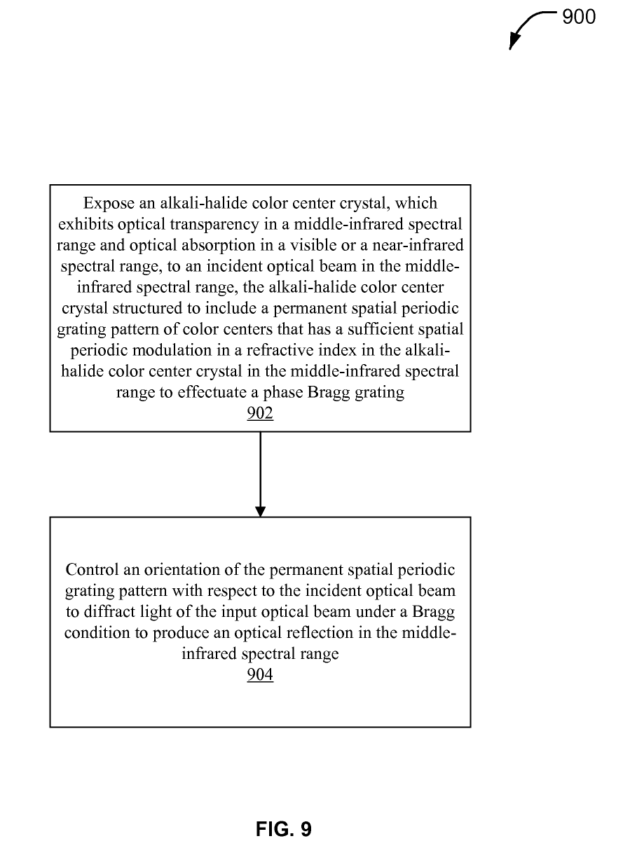

One method for using a volumetric Bragg grating formed of an alkali-halide crystal with color centers is to diffract light in a mid-IR spectral range to produce optical reflection such as retro-reflection. This method illustrated in FIG. 9, in which, at 902, an alkali-halide color center crystal, which exhibits optical transparency in a middle-infrared spectral range and optical absorption in a visible or a near-infrared spectral range, is exposed to an incident optical beam in the middle-infrared spectral range. The alkali-halide color center crystal is structured to include a permanent spatial periodic grating pattern of color centers that has a sufficient spatial periodic modulation in a refractive index in the alkali-halide color center crystal in the middle-infrared spectral range to effectuate a phase Bragg grating. The spatial period of the grating is set by the Bragg condition for an optical wavelength in the mid-IR spectral range and is longer than grating periods of gratings designed for the visible and near-IR spectral ranges. Referring back to FIG. 9, at 904, the orientation of the permanent spatial periodic grating pattern with respect to the incident optical beam is controlled to diffract light of the input optical beam under a Bragg condition to produce an optical reflection in the middle-infrared spectral range. For example, the incident optical beam can be at a wavelength in a range from 2 μm to 6 μm where there has been no commercial color center crystal-based VBGs available.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described above should not be understood as requiring such separation in all embodiments.

Only a few implementations and examples are described and other implementations, enhancements and variations can be made based on what is described and illustrated in this patent document.

What is claimed is:

1. A volumetric Bragg grating device for operating in a mid-infrared spectral range, comprising:
an alkali-halide crystal including a plurality of color centers with wide spectral transparency in a mid-infrared spectral range, the alkali-halide crystal structured to exhibit variations in a refractive index of the alkali-halide crystal in the mid-infrared spectral range through selective removal of at least a subset of the plurality of color centers to form a volumetric Bragg grating that operates in the mid-infrared spectral range.

2. The device of claim 1, wherein the alkali-halide crystal is a lithium fluoride (LiF) crystal.

3. The device of claim 1, wherein the alkali-halide crystal is structured by photo-induced bleaching of the subset of color centers.

4. The device of claim 1, wherein the variation in refractive index is at least 10⁻⁴ in a spectral range spanning approximately 1 to 6 micrometers.

5. The device of claim 1, wherein the volumetric Bragg grating exhibits an efficiency in the range of approximately 10 to 100 percent within a spectral range spanning approximately 1 to 6 micrometers.

6. The device of claim 1, wherein the volumetric Bragg grating includes grooves that are formed as spatial variations in the refractive index as a result of selective removal of the plurality of color centers.

7. The device of claim 1, wherein the selective removal includes photo-induced bleaching of the subset of the plurality of color centers.

8. The device of claim 1, wherein the plurality of color centers is formed within the alkali-halide crystal by ionizing radiation and/or additive or electrolytic coloration.

9. The device of claim 1, further being configured to operate as an output coupler or reflector of a laser cavity.

10. A method for producing a volumetric Bragg grating device for operating in a mid-infrared spectral range, comprising:
obtaining an alkali-halide crystal comprising a plurality of color centers; and
selectively removing a subset of the plurality of color centers to produce spatial variations in a refractive index of the alkali-halide crystal in the mid-infrared spectral range to effectuate a volumetric Bragg grating that operates in the mid-infrared spectral range.

11. The method of claim 10, wherein the alkali-halide crystal is a Lithium Flouride (LiF) crystal.

12. The method of claim 10, wherein obtaining the alkali-halide crystal comprising the plurality of color centers comprises exposing the alkali-halide crystal to an ionizing radiation and/or through additive or electrolytic coloration to form the plurality of color centers.

13. The method of claim 10, wherein selectively removing the subset of the plurality of color centers comprises photo-induced bleaching of the subset of color centers.

14. The method of claim 13, wherein the photo-induced bleaching comprises:
(a) exposing the alkali-halide crystal comprising the plurality of color centers to a laser beam to form a first groove;
(b) shifting the position of the alkali-halide crystal;
(c) subsequent to the shifting, exposing the alkali-halide crystal to the laser beam form a second groove; and
(d) repeating steps (b) and (c) a predetermined number of times to form additional grooves.

15. The method of claim 10, wherein selectively removing the subset of the plurality of color centers comprises directing two or more coherent optical beams to the alkali-halide crystal to cause formation of the volumetric Bragg grating using an interference pattern of the two or more beams.

16. The method of claim 10, wherein selectively removing the subset of the plurality of color centers is carried out through an electron or ion beam lithography.

17. The method of claim 10, wherein the variation in refractive index is at least 10⁻⁴ in a spectral range spanning approximately 1 to 6 micrometers.

18. The method of claim 10, wherein selectively removing the plurality of color centers produces spatial variations in the refractive index that form a plurality of grooves of the volumetric Bragg grating.

19. The method of claim 10, wherein the volumetric Bragg grating exhibits an efficiency in the range from approximately 10 percent to 100 percent in a spectral range spanning approximately 1 to 6 micrometers.

20. A laser system comprising the volumetric Bragg grating device of claim 1, wherein the volumetric Bragg grating device is configured to operate as an output coupler or reflector of a laser cavity of the laser system.

21. A method for using a volumetric Bragg grating formed of an alkali-halide crystal with color centers to diffract light in a mid-IR spectral range to produce optical reflection, comprising:
exposing an alkali-halide color center crystal, which exhibits optical transparency in a middle-infrared spectral range and optical absorption in a visible or a near-infrared spectral range, to an incident optical beam in the middle-infrared spectral range, the alkali-halide color center crystal structured to include a permanent spatial periodic grating pattern of color centers that has a sufficient spatial periodic modulation in a refractive index in the alkali-halide color center crystal in the middle-infrared spectral range to effectuate a phase Bragg grating; and
controlling an orientation of the permanent spatial periodic grating pattern with respect to the incident optical beam to diffract light of the input optical beam under a Bragg condition to produce an optical reflection in the middle-infrared spectral range.

22. The method as in claim 21, wherein the color centers in the alkali-halide color center crystal are formed by exposing an alkali-halide crystal to ionizing radiation and/or additive or electrolytic coloration.

23. The method as in claim 21, wherein the permanent spatial periodic grating pattern of color centers in the alkali-halide color center crystal is formed by photo-bleaching.

24. The method as in claim 21, wherein the permanent spatial periodic grating pattern of color centers in the alkali-halide color center crystal is formed by an electron or ion beam lithography.

25. The method as in claim 21, wherein the incident optical beam is at a wavelength in a range from 2 μm to 6 μm.

26. The method as in claim 21, comprising operating the alkali-halide color center crystal under a room temperature.

27. The method as in claim 21, comprising including the alkali-halide color center crystal as part of laser cavity to use the phase Bragg grating to provide optical reflection in the laser cavity.
